(19) United States
(12) Patent Application Publication
(10) Pub. No.: US 2026/0225680 A1
(43) Pub. Date: Aug. 6, 2026

(54) ELECTRIC VEHICLE WITH SOUND WAVE FUNCTION

(71) Applicant: Dongguan Wind Horse New Energy Technology Limited, Dongguan (CN)

(72) Inventor: SHENGLI ZHU, Huangshan (CN)

(21) Appl. No.: 19/632,151

(22) Filed: Mar. 27, 2026

(30) Foreign Application Priority Data
Feb. 9, 2026 (CN) 202610180254.9

(51) Int. Cl. B62J 45/10; B62J 3/10; B62J 45/20; B62K 11/02; B62K 23/02; G10K 15/04; H03F 3/21; H04R 1/02; H04R 3/00; B62L 1/00

(52) U.S. Cl. CPC B62J 45/10; B62J 3/10; B62J 45/20; B62K 11/02; B62K 23/02; G10K 15/04; H03F 3/21; H04R 1/025; H04R 3/00; B62K 2204/00; B62L 1/00; H03F 2200/03; H04R 2420/07; H04R 2499/13

(57) ABSTRACT

Provided is an electric vehicle with sound wave function, which includes a frame, wheels, a saddle, a speed controller, a horn, and a control system. The wheels are provided on the frame, the saddle is provided on the frame, and the control system is provided inside the frame. The speed controller is directly or indirectly provided with the frame and is electrically connected to the control system. The speed controller outputs a speed control signal to the control system. The horn is provided on the frame and is electrically connected to the control system. The frame of the electric vehicle is fixedly provided with the horn, an audio amplifier is connected to the electric vehicle speed controller to collect a speed control signal of the electric vehicle speed controller. According to the strength of the speed control signal, the horn is controlled to play sound effects.

### CROSS-REFERENCE TO RELATED APPLICATIONS

This application claims priority to Chinese Patent Application No. 202610180254.9, filed on February 09, 2026, which is hereby incorporated by reference in its entirety.

### TECHNICAL FIELD

The present disclosure relates to the field of personal transportation technologies, and discloses to an electric vehicle, in particular, to an electric vehicle with sound wave function.

### BACKGROUND

Electric bicycles are two wheeled vehicles that use on-board lithium batteries/rechargeable batteries as auxiliary energy, can ride on foot, and can achieve electric assistance/drive. They belong to non-motorized vehicles. Electric motorcycles are electric powered motorcycles that usually do not have pedal functions. Electric motorcycles can be divided into lightweight electric motorcycles (maximum speed ≤ 50km/h) and ordinary electric motorcycles (maximum speed>50km/h), both of which are motor vehicles.

Whether it is an electric bicycle or an electric motorcycle, as they are both driven by an electric motor, there is no sound throughout the entire process. For those who pursue speed and passion, the roar of traditional gasoline car engines (often referred to as “sound waves”) can cause inexplicable excitement. However, electric vehicles do not have sound waves due to the lack of engine mechanisms, and for certain specific groups of people, they always feel a lack of auditory satisfaction.

### SUMMARY

The present disclosure provides an electric vehicle with sound wave function, which is fixed on an electric vehicle frame with a horn. The audio amplifier is connected to an electric vehicle speed controller, collects a speed control signal of the electric vehicle speed controller, and controls the horn to play sound wave effects according to the strength of the speed control signal, so that the electric vehicle can achieve the effect of sound wave function.

The technical solution adopted by the present disclosure to solve its technical problem is: an electric vehicle with sound wave function, including: a frame, wheels, a saddle, a speed controller, a horn, and a control system; the wheels are provided on the frame, the saddle is provided on the frame, and the control system is provided inside the frame; the speed controller is directly or indirectly provided with the frame, and the speed controller is electrically connected to the control system; the speed controller outputs a speed control signal to the control system, the horn is provided on the frame, and the horn is electrically connected to the control system.

The technical solution adopted by the present disclosure to solve its technical problem further includes that a handlebar is provided on the frame, and a speed controller is provided at a position of a right-hand handle sleeve of the handlebar.

A break is further provided on the handlebar.

The horn is provided below the saddle.

The control system includes a central control module, a speed controller interface, a driving module, a motor, an audio power amplifier module, and a speaker; the speed controller interface is connected to the central control module, the driving module is connected to the central control module, the audio power amplifier module is connected to the central control module, and the speaker is connected to the audio power amplifier module.

The speed controller adopts a Hall speed control handle.

The motor adopts a brushless motor, and the driving module includes a first driving module, a second driving module, and a third driving module, the first driving module, the second driving module, and the third driving module are respectively connected to the motor.

The central control module is further connected to a Bluetooth module, and the Bluetooth module is connected to the audio power amplifier module.

A brake module is connected to the central control module.

The central control module is connected to a motor Hall interface, and a motor Hall module is connected to the motor Hall interface.

The beneficial effects of the present disclosure are: the speaker is fixedly provided on the frame of the electric vehicle, the audio amplifier is connected to the electric vehicle speed controller, the speed control signal of the electric vehicle speed controller is collected, and the speaker is controlled to play sound effects according to the strength of the speed control signal, so that the electric vehicle can achieve the effect of sound waves and meet people’s psychological needs.

The present disclosure will be further explained in combination with the accompanying drawings and specific embodiments.

### BRIEF DESCRIPTION OF DRAWINGS

FIG. 1 is a schematic diagram of a first three-dimensional structure of the present disclosure.

FIG. 2 is a schematic diagram of a second perspective three-dimensional structure of the present disclosure.

FIG. 3 is a circuit block diagram of the present disclosure.

FIG. 4 is a schematic diagram of a motor control circuit in the present disclosure.

FIG. 5 is a schematic diagram of an audio power amplifier circuit in the present disclosure.

FIG. 6 is a schematic diagram of a circuit of a Bluetooth module in the present disclosure.

Numeral reference: 1- frame, 2- wheel, 3- saddle, 4- handlebar, 5- speed controller, 6- brake, 7- horn.

### DESCRIPTION OF EMBODIMENTS

The embodiments are preferred embodiments of the present disclosure, and any other principles and basic structures that are the same or similar to the embodiments are within the protection scope of the present disclosure.

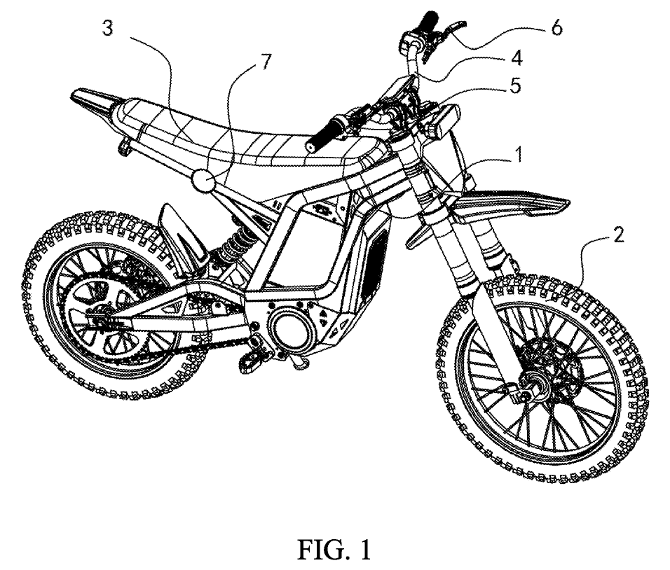

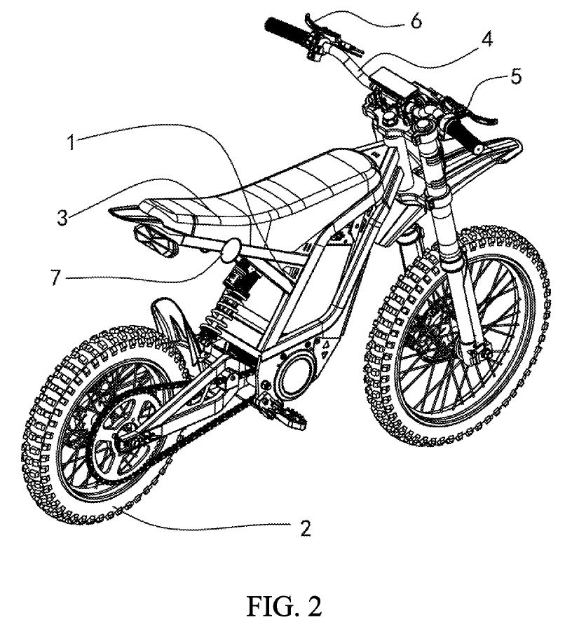

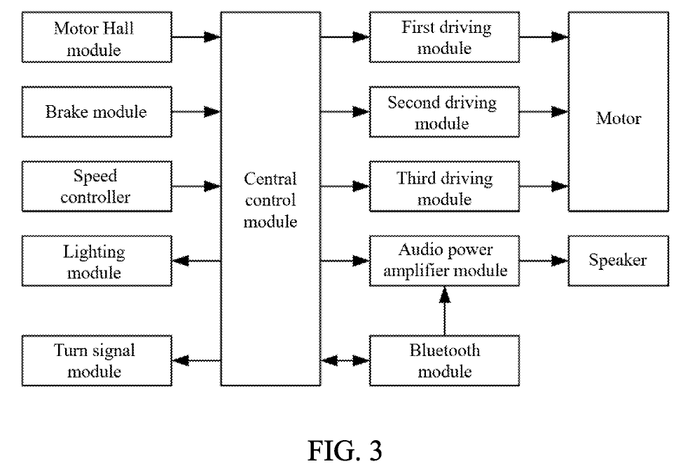

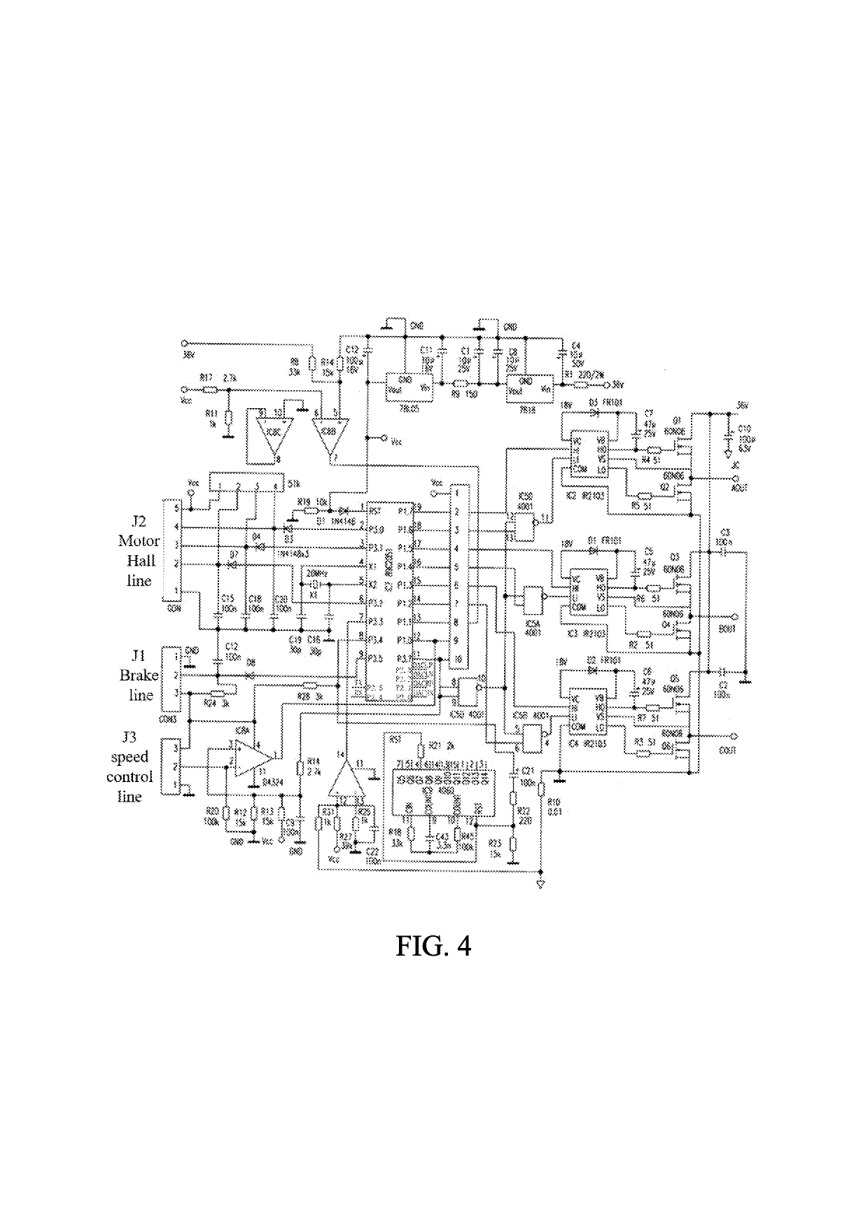

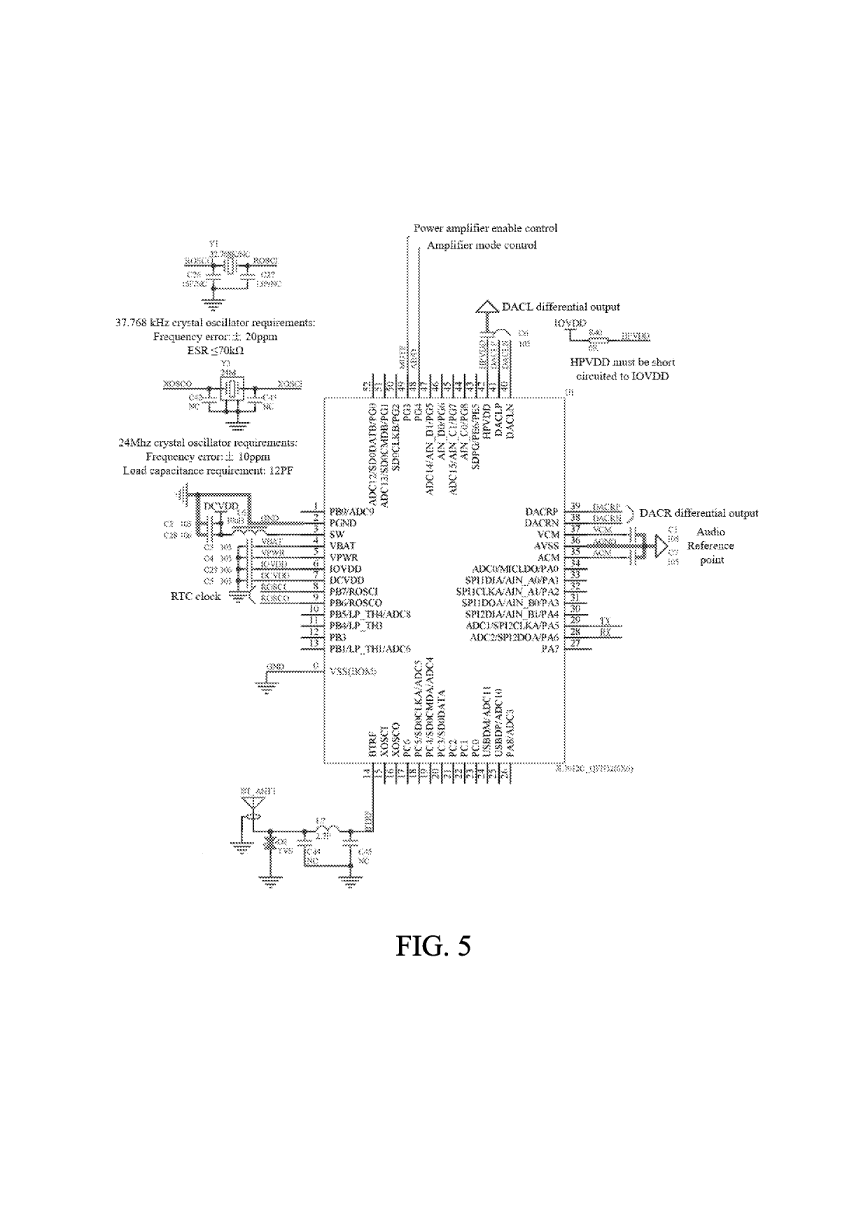

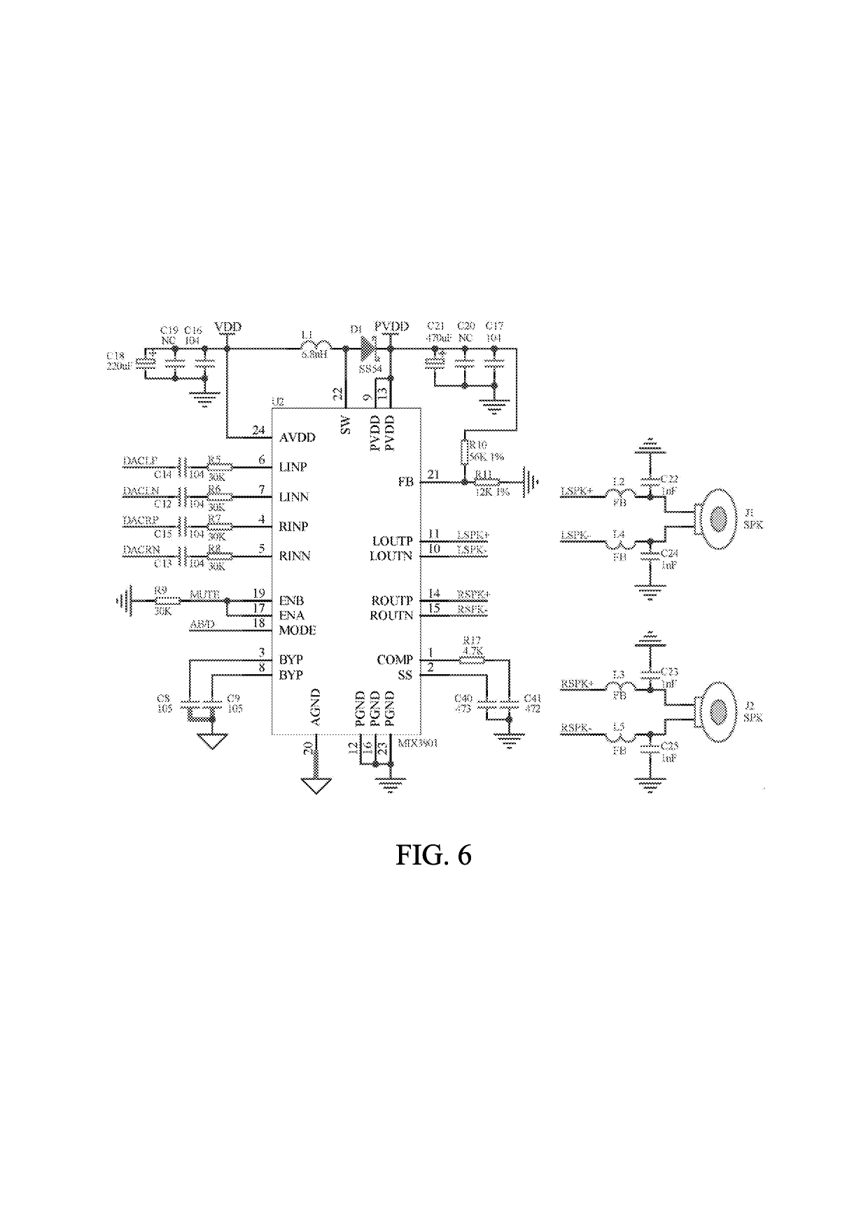

Please refer to FIGS. 1 to 6. The present disclosure mainly protects an electric vehicle with sound wave function, which mainly includes a frame 1, wheels 2, a saddle 3, a speed controller 5, a horn 7, and a control system. The wheels 2 are provided on the frame 1, the saddle 3 is provided on the frame 1, and the control system is provided inside the frame 1. The speed controller 5 is directly or indirectly provided together with the frame 1, and is electrically connected to the control system. The speed controller 5 outputs a speed control signal to the control system. The horn 7 is provided on the frame 1 and is electrically connected to the control system and drives the horn 7 to emit sound waves through the control system. When the speed controller 5 adjusts a speed, a speed control signal is transmitted to the control system, and the control system drives it according to the size of the speed control signal. The electric motor rotates, and the vehicle is driven forward by the motor. On the other hand, the control system controls the frequency and magnitude of the sound wave emitted by the horn 7 based on the magnitude of the speed control signal, which can simulate the sound wave emitted by traditional gasoline motorcycles during acceleration and meet people’s psychological needs.

In this embodiment, the handlebar 4 is provided on the frame 1, and the speed regulator 5 is provided at a position of a right handlebar sleeve of the handlebar 4, which not only conforms to people’s daily usage habits but also further enhances the simulation effect. Combined with tactile and auditory feedback, it can better meet people’s psychological needs.

In this embodiment, the handlebar 4 is further provided with a brake 6, and the brake 6 can be used to pull a brake line for braking operation.

In this embodiment, the horn 7 is preferably provided below the saddle 3, close to a position of an exhaust pipe of traditional gasoline motorcycles, and the sound wave simulation effect is more realistic. One or two horns 7 can be arranged according to actual needs. In this embodiment, taking two as examples, one is provided on each side of the frame 1.

In this embodiment, the control system mainly includes a central control module, a speed controller interface, a driving module, a motor, an audio power amplifier module, and a speaker (i.e. a horn 7, which is both a part of the control system and a structural component). The speed controller interface is connected to the central control module for installing and connecting the speed controller 5, and the driving module is connected to the central control module. The central control module outputs a control signal to the driving module, which drives the motor to rotate. In this embodiment, the motor can use a wheel hub motor, which directly drives the wheels 2 to rotate through the motor. The motor can also use a regular motor, which drives the wheels 2 to rotate through a transmission device (such as a chain, gear, belt, connection rod, etc., preferably using the chain). The audio power amplifier module is connected to the central control module. The audio signal is output to the audio power amplifier module through the central control module. In this embodiment, the audio signal of the sound wave is stored in the central control module (or an external storage module). When in use, the central control module directly retrieves the audio signal of the sound wave and transmits it to the audio power amplifier module. The speaker is connected to the audio power amplifier module and drives the speaker (i.e. horn 7) to produce sound through the audio power amplifier module.

In this embodiment, the central control module can use a microcontroller as a Microcontroller Unit, (MCU), and conventional small microcontroller such as 51 series, Texas Instruments, (TI) series, Peripheral Interface Controller, (PIC) series, etc. can be used to meet the requirements. In this embodiment, 51 series is taken as an example for explanation.

In this embodiment, the speed controller 5 is connected to a speed controller interface. The speed controller 5 can use a Hall speed control handle (also known as a Hall handle) to turn an angle of the handle into a continuous voltage signal, so that the central control module can achieve stepless speed regulation, which is more durable and anti-interference than the potentiometer handle. Of course, the potentiometer handle can also be used as the speed controller 5 in specific implementation.

In this embodiment, the motor is preferably a brushless motor driven by three motor driving chips. The driving modules include a first driving module, a second driving module, and a third driving module. The first driving module, the second driving module, and the third driving module are respectively connected to the motor, and the motor is driven to rotate through the first driving module, the second driving module, and the third driving module. In this embodiment, the driving module can use a IR2013 half bridge gate driving chip. In specific implementation, other types of driving chips can also be used instead.

In this embodiment, the central control module is further connected to a Bluetooth module, and the Bluetooth module can be used to connect with a mobile phone and other devices. Music and other audio can be played using the mobile phone, transmitted to the present disclosure through Bluetooth, and then played using the horn 7, using the present disclosure as a Bluetooth horn. In this embodiment, the Bluetooth module can use a JL7012C Bluetooth chip, which is connected to the central control module through a serial interface (TX and RX interfaces). In specific implementation, other types of Bluetooth chips can also be used. In this embodiment, when using the Bluetooth function, the central control module controls the sound wave signal to stop outputting, and only uses horn 7 as a Bluetooth horn. In specific implementation, a conversion switch can also be provided for users to choose and operate, thereby increasing the convenience of use.

In this embodiment, a brake module is further connected to the central control module, and the brake module is linked to the brake 6. When the user holds the brake 6, the brake module outputs a brake signal to the central control module. When the brake signal is present, the speed controller 5 is rotated, and the central control module only controls the output of the sound wave signal and does not output the motor drive signal. It can simulate the sound wave emitted by a motorcycle holding the clutch and rotating the throttle lever. Of course, during the driving process of the vehicle, when the brake 6 is held, the horn 7 can also simulate the sound of braking or the sound of tires rubbing against the ground. The specific implementation can be set according to the needs.

In this embodiment, a motor Hall interface is further connected to the central control module, and a motor Hall module is connected to the motor Hall interface. The motor speed can be detected through the motor Hall module and fed back to the central control module.

The central control module can also be connected to a conventional electric vehicle module such as a lighting module, a turn signal module, a power detection module, a display module, etc., which are not the focus of the present disclosure and can all use conventional modules in existing technologies.

The present disclosure fixedly installs the speaker on the electric vehicle frame, and the audio amplifier is connected to the electric vehicle speed controller to collect the speed control signal of the electric vehicle speed controller. Based on the strength of the speed control signal, the horn is controlled to play sound effects, so that the electric vehicle can achieve the effect of sound waves and meet people’s psychological needs.

What is claimed is:

1. An electric vehicle with sound wave function, comprising: a frame, wheels, a saddle, a speed controller, a horn, and a control system;
the wheels are provided on the frame, the saddle is provided on the frame, and the control system is provided inside the frame;
the speed controller is directly or indirectly provided with the frame, and the speed controller is electrically connected to the control system;
the speed controller outputs a speed control signal to the control system, the horn is provided on the frame, and the horn is electrically connected to the control system.

2. The electric vehicle with sound wave function according to claim 1, wherein a handlebar is provided on the frame, and a speed controller is provided at a position of a right-hand handle sleeve of the handlebar.

3. The electric vehicle with sound wave function according to claim 2, wherein a brake is further provided on the handlebar.

4. The electric vehicle with sound wave function according to claim 1, wherein the horn is provided below the saddle.

5. The electric vehicle with sound wave function according to claim 1, wherein the control system comprises a central control module, a speed controller interface, a driving module, a motor, an audio power amplifier module, and a speaker;
the speed controller interface is connected to the central control module, the driving module is connected to the central control module, the audio power amplifier module is connected to the central control module, and the speaker is connected to the audio power amplifier module.

6. The electric vehicle with sound wave function according to claim 1, wherein the speed controller adopts a Hall speed control handle.

7. The electric vehicle with sound wave function according to claim 5, wherein the motor adopts a brushless motor, and the driving module comprises a first driving module, a second driving module, and a third driving module, the first driving module, the second driving module, and the third driving module are respectively connected to the motor.

8. The electric vehicle with sound wave function according to claim 5, wherein the central control module is further connected to a Bluetooth module, and the Bluetooth module is connected to the audio power amplifier module.

9. The electric vehicle with sound wave function according to claim 5, wherein a brake module is connected to the central control module.

10. The electric vehicle with sound wave function according to claim 5, wherein the central control module is connected to a motor Hall interface, and a motor Hall module is connected to the motor Hall interface.
